(19) United States
(12) Patent Application Publication
(10) Pub. No.: US 2026/0146321 A1
(43) Pub. Date: May 28, 2026

(54) METHOD TO DEPOSIT A SILICON CARBIDE LAYER

(71) Applicant: ASM IP Holding B.V., Almere (NL)

(72) Inventors: Ville Liimatainen, Espoo (FI); René Henricus Jozef Vervuurt, Leuven (BE); Viljami Pore, Helsinki (FI)

(21) Appl. No.: 19/398,200

(22) Filed: Nov. 24, 2025

Related U.S. Application Data
(60) Provisional application No. 63/726,112, filed on Nov. 27, 2024.

(51) Int. Cl. C23C 16/455; C23C 16/32; C23C 16/36; C23C 16/44

(52) U.S. Cl. CPC C23C 16/45538; C23C 16/325; C23C 16/36; C23C 16/4408; C23C 16/45553

(57) ABSTRACT

A method for depositing a silicon carbide layer on a substrate is disclosed. The method including: providing a substrate in a reaction chamber; providing a precursor and a reactant in the reaction chamber and forming a soft plasma in the reaction chamber; and purging the reaction chamber. Further, it included providing an inert gas in the reaction chamber and forming a strong plasma in the reaction chamber with a larger power than the soft plasma.

### CROSS-REFERENCE TO RELATED APPLICATIONS

This application claims priority to U.S. Provisional Patent Application Ser. No. 63/726,112 filed Nov. 27, 2024 and titled METHOD TO DEPOSIT A SILICON CARBIDE LAYER, the disclosure of which is hereby incorporated by reference in its entirety.

### FIELD OF INVENTION

The present disclosure relates generally to depositing a silicon carbide layer on a substrate. The present disclosure more specifically relates to using plasma to deposit silicon carbide (SiC).

### BACKGROUND OF THE DISCLOSURE

Semiconductor fabrication processes for forming semiconductor device structures, such as, for example, transistors, memory elements, and integrated circuits, are wide ranging and may include deposition processes. The deposition process may be depositing a silicon carbide (SiC) layer on a substrate.

The structures on the substrate may comprise hollow features accessible via openings in the surface of the substrate. The deposition processes of the silicon carbide layer on the substrate may become challenging if the deposited layer needs to be deposited inside the hollow feature as well via the opening and the layer needs to have a uniform thickness.

Atomic layer deposition (ALD) process may be used to achieve these conformal uniform layers it has however been difficult for the silicon carbide layers to achieve good quality layers with ALD. The layers may be applied as spacers in which the dielectric constant of the layer may be an important quality. It may be difficult to find a layer with a sufficiently low dielectric constant.

Accordingly, there is a need for a deposition process for silicon carbide that is able to achieve uniform layers also inside hollow features on the substrate.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In at least one embodiment of the invention, a method to deposit a silicon carbide layer on a substrate is provided. The method may comprise: providing a substrate in a reaction chamber; providing a precursor and a reactant (such as for example hydrogen) in the reaction chamber and forming a soft plasma in the reaction chamber; purging the reaction chamber; and, providing an inert gas in the reaction chamber and forming a strong plasma in the reaction chamber with a larger power than the soft plasma. The soft plasma may help to provide reactive species of the precursor and the reactant so that a uniform layer may be provided over the substrate with a good growth. The strong plasma may further improve the quality of the uniform layer and finalize it.

In at least one embodiment of the invention the substrate may comprise a hollow feature accessible via an opening in the surface of the substrate and the soft plasma provides reactive species of the precursor and the reactant in the hollow feature via the opening. Having reactive species provided through the opening may help to provide a uniform layer in the hollow feature.

In at least an embodiment of the invention a layer may be deposited with a density between 1.7 and 2.1 g/cm³. Having such a low density may result in the layer having a low k value which is advantageous.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates a non-limiting exemplary process flow, demonstrating a method for depositing a silicon carbide layer on a substrate.

FIGS. 2a, 2b and 2c illustrate the structure formula of precursors which can be used in the method of FIG. 1.

The illustration presented herein is not meant to be actual views of any particular material, structure, or device, but are merely idealized representations that are used to describe embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials that may be used, or upon which, a device, a circuit, or a layer may be formed.

As used herein, the term “cyclical chemical vapor deposition” may refer to any process wherein a substrate is sequentially exposed to one or more volatile precursors, which react and/or decompose on a substrate to produce a desired deposition.

As used herein, the term precursor may refer to a precursor for depositing silicon carbide. The precursor may comprise silicon, oxygen, hydrogen, nitrogen and carbon atoms.

As used herein, the term precursor may refer to a precursor comprising a substituent selected from the group consisting of an acetoxy group, an acryloyloxy group, a silyloxy group, a germyloxy group, a phosphonooxy group, and an alkyl amine group.

As used herein, the term precursor may refer to a precursor comprising an alkoxy group such as an ethoxy group. The precursor may comprise two to six ethoxy groups.

As used herein, the term precursor may refer to a precursor selected from the group of 1,1,3,3,5,5-Hexaethoxy-1,3,5-trisilacyclohexane (C₁₅H₃₆O₆Si₃), Methacryloxymethyltriethoxysilane (C₁₁H₂₂O₅Si) and 1,3-Diethoxy-1,2-dimethyl-1,3-disilacyclobutane (C₈H₂₀O₂Si₂).

As used herein, the term plasma may refer to a state of matter characterized by the presence of a significant portion of charged particles in any combination of ions or electrons.

As used herein, the term reactant may refer to a gas comprising hydrogen, oxygen, nitrogen or any mixture thereof.

As used herein, the term “atomic layer deposition” (ALD) may refer to a vapor deposition process in which deposition cycles, preferably a plurality of consecutive deposition cycles, are conducted in a reaction chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “layer” and “thin layer” may refer to any continuous or non-continuous structures and material formed by the methods disclosed herein. For example, “layer” and “thin layer” could include 2D materials, nanolaminates, nanorods, nanotubes, or nanoparticles, or even partial or full molecular layers, or partial or full atomic layers or clusters of atoms and/or molecules. “Layer” and “thin layer” may comprise material or a layer with pinholes, but still be at least partially continuous.

A number of example materials are given throughout the embodiments of the current disclosure, it should be noted that the chemical formulas given for each of the materials should not be construed as limiting and that the non-limiting example materials given should not be limited by a given example stoichiometry.

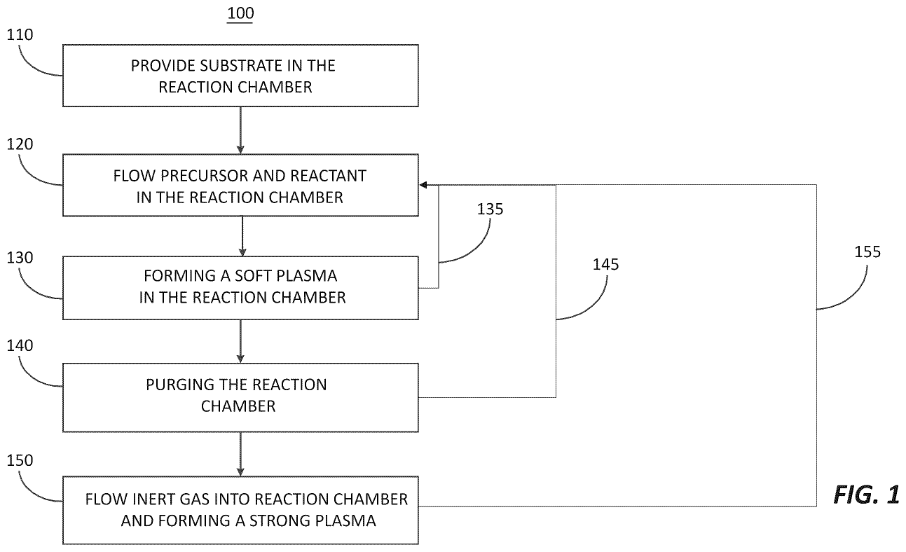

FIG. 1 illustrates a method 100 for depositing a silicon carbide layer on a substrate. In at least one embodiment of the invention, the method may comprise: providing a substrate in a reaction chamber 110; providing a precursor and a reactant (such as for example hydrogen) in the reaction chamber 120 and forming a soft plasma in the reaction chamber 130. These steps may be repeated 135 until sufficient precursor and reactant is provided to the substrate. Thereafter the method may proceed with purging the reaction chamber 140. Again, these steps may be repeated 145 now with the purging step included if needed. Thereafter the method may comprise providing an inert gas in the reaction chamber and forming a strong plasma in the reaction chamber 150 with a larger power than the soft plasma. Again, these steps may be repeated 155 now with the strong plasma included. The soft plasma may help to provide reactive species of the precursor and the reactant so that a uniform layer may be provided over the substrate. The strong plasma may further improve the quality of the uniform layer and finalize the layer.

In at least one embodiment of the invention the substrate may comprise a hollow feature accessible via an opening in the surface of the substrate and the soft plasma provides reactive species of the precursor and the reactant in the hollow feature via the opening. Having reactive species provided through the opening may help to provide a uniform layer in the hollow feature.

In at least an embodiment the plasma may be a continuous wave plasma. A continuous wave plasma may have the right properties to activate the precursor.

In at least an embodiment the strong plasma has a power between 10 to 2, preferably 7 to 2.5, and more preferably 5 to 3 times higher than the soft plasma. For example, the soft plasma may have a power between 5 to 100, preferably 10 to 50, and more preferably 20 to 35 Watt. For example, the strong plasma may have a power between 50 to 200, preferably 75 to 150, and most preferably 90 to 125 W. With these powers the soft plasma may be strong enough to activate the precursor and the reactant while it may be too weak to damage the precursor and reactant. The strong plasma may solidify and/or improve the already deposited layer. That the layer is already deposited may protect the layer also from damage by the strong plasma.

In at least an embodiment a silicon oxycarbide layer may be deposited. The inclusion of oxygen may be beneficial for some applications.

In at least an embodiment the precursor comprises a substituent selected from the group consisting of an acetoxy group, an acryloyloxy group, a silyloxy group, a germyloxy group, a phosphonooxy group, and an alkyl amine group. These groups may bring in the right chemistry while at the same time provide the required reactivity.

In an embodiment the precursor comprises an alkoxy group. The alkoxy group may comprise an ethoxy group. The precursor may comprise two to six ethoxy groups.

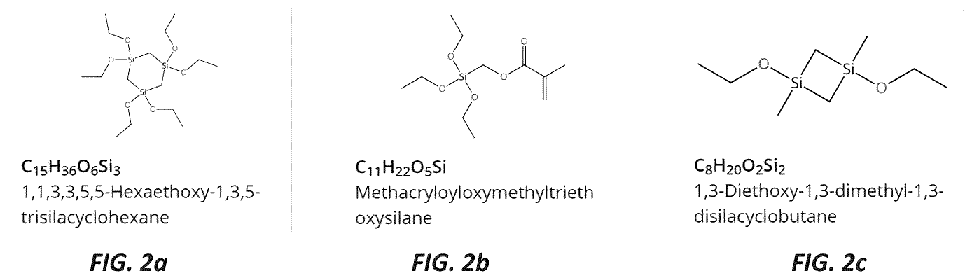

FIGS. 2a, 2b and 2c illustrate the structure formula of precursors for use in the method of FIG. 1. In an embodiment the precursor may be selected from the group of 1,1,3,3,5,5-Hexaethoxy-1,3,5-trisilacyclohexane (C₁₅H₃₆O₆Si₃) (see FIG. 2a), Methacryloxymethyltriethoxysilane (C₁₁H₂₂O₅Si) (see FIG. 2b) and 1,3-Diethoxy-1,2-dimethyl-1,3-disilacyclobutane (C₈H₂₀O₂Si₂) (see FIG. 2c).

In an embodiment the precursor may comprise silicon, oxygen, hydrogen, nitrogen and carbon atoms. This brings the right chemistry into the layer.

In an embodiment the reactant may comprise hydrogen, oxygen, nitrogen or any mixture thereof. The reactants may be activated by the plasma.

In an embodiment the inert gas forming the plasma comprises a gas selected from the group comprising Argon, Helium, Neon, Krypton and Xenon. The inert gas may be activated by the plasma while not reacting with the deposited layer.

In an embodiment the plasma comprises nitrogen. This may enable the deposition of nitrogen in the deposited layer.

In an embodiment a silicon oxycarbide nitride layer is deposited. The inclusion of oxygen and nitrogen may be beneficial for some applications.

In an embodiment a silicon carbon nitride layer is deposited. The inclusion of nitrogen may be beneficial for some applications.

In an embodiment the method comprises after providing the strong plasma:
purging the reaction chamber
providing the precursor and the reactant in the reaction chamber and forming a soft plasma in the reaction chamber;
purging the reaction chamber; and,
providing an inert gas in the reaction chamber and forming a strong plasma in the reaction chamber with a larger power than the soft plasma. In this way the layer can be build up from multiple silicon carbide layers.

Table 1 (below) depicts some properties of layers deposited with the precursor 1,1,3,3,5,5-Hexaethoxy-1,3,5-trisilacyclohexane and hydrogen as the reactant. According to the invention the precursor, reactant and soft plasma was provided for 1 second, the purge was provided for 5 seconds and the strong plasma for 0.3 second. The soft plasma had a power of 25 to 35 Watts and the strong plasma had a power of 100 Watts. The growth per cycle was 0.6 to 3.2 Angstrom per cycle. A layer deposited with the method may have a density between 1.7 and 2.1 g/cm³ and a k value of about 3.5.

TABLE 1

| Temp | | Density | | Side wall |
|---|---|---|---|---|
| (Celsius) | Process | (g/cm³) | k value | conformality |
| 200 | According to the prior | 2.23-2.35 | 3.8 | 85% CD 65 nm |
| | art | | | |
| 200 | According to the | 1.72-2.00 | 3.5 | 95% CD 25 nm |
| | invention | | | |

Having a low density indicates a high porosity. A high porosity gives the layer a low dielectric constant (i.e. low k value) because air has a relatively low dielectric constant which is advantageous in the application of the layers as a spacer.

In the prior art example the (one) plasma had a power of 100 to 300 Watts for 0.5 to 2 seconds. The growth per cycle was 0.06 to 0.14 Angstrom per cycle. A layer deposited with the method may have a density between 2.23 and 2.35 g/cm³ and a k value of about 3.8.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A method to deposit a silicon carbide layer on a substrate, the method comprising:
providing a substrate in a reaction chamber;
providing a precursor and a reactant in the reaction chamber and forming a soft plasma in the reaction chamber;
purging the reaction chamber; and,
providing an inert gas in the reaction chamber and forming a strong plasma in the reaction chamber with a larger power than the soft plasma.

2. The method according to claim 1, wherein the substrate comprises a hollow feature accessible via an opening in the surface of the substrate and the soft plasma provides reactive species of the precursor and the reactant in the hollow feature via the opening.

3. The method according to claim 1, wherein the plasma is a continuous wave plasma.

4. The method according to claim 1, wherein the strong plasma has a power between 10 to 2, preferably 7 to 2.5, and more preferably 5 to 3 times higher than the soft plasma.

5. The method according to claim 4, wherein the soft plasma has a power between 5 to 100, preferably 10 to 50, and more preferably 20 to 35 Watt.

6. The method according to claim 4, wherein the strong plasma has a power between 50 to 200, preferably 75 to 150, and most preferably 90 to 125 Watt.

7. The method according to claim 1, wherein a silicon oxycarbide layer is deposited.

8. The method according to claim 1, wherein the precursor comprises a substituent selected from the group consisting of an acetoxy group, an acryloyloxy group, a silyloxy group, a germyloxy group, a phosphonooxy group, and an alkyl amine group.

9. The method according to claim 1, wherein the precursor comprises an alkoxy group.

10. The method according to claim 9, wherein the alkoxy group comprises an ethoxy group.

11. The method according to claim 9, wherein the precursor comprises two to six ethoxy groups.

12. The method according to claim 9, wherein the precursor is selected from the group of 1,1,3,3,5,5-Hexaethoxy-1,3,5-trisilacyclohexane (C₁₅H₃₆O₆Si₃), Methacryloxymethyltriethoxysilane (C₁₁H₂₂O₅Si) and 1,3-Diethoxy-1,2-dimethyl-1,3-disilacyclobutane (C₈H₂₀O₂Si₂).

13. The method according to claim 1, wherein the precursor comprises silicon, oxygen, hydrogen, nitrogen and carbon atoms.

14. The method according to claim 1 wherein the reactant comprises hydrogen, oxygen, nitrogen or any mixture thereof.

15. The method according to claim 1, wherein the inert gas forming the plasma comprises a gas selected from the group comprising Argon, Helium, Neon, Krypton and Xenon.

16. The method according to claim 1, wherein the plasma comprises nitrogen.

17. The method according to claim 16, wherein a silicon oxycarbide nitride layer is deposited.

18. The method according to claim 16, wherein silicon carbon nitride is deposited.

19. The method according to claim 18, wherein the silicon carbide nitride layer comprises less than 5% carbon.

20. The method according to claim 1, wherein the method comprises after providing the strong plasma:
purging the reaction chamber
providing the precursor and the reactant in the reaction chamber and forming a soft plasma in the reaction chamber,
purging the reaction chamber, and,
providing an inert gas in the reaction chamber and forming a strong plasma in the reaction chamber with a larger power than the soft plasma.

21. A layer deposited with the method according to claim 1, wherein the density of layer is between 1.7 and 2.1 g/cm³.
